(19) United States
(12) Patent Application Publication
(10) Pub. No.: US 2023/0395015 A1
(43) Pub. Date: Dec. 7, 2023

(54) Systems With External Displays

(71) Applicant: Apple Inc., Cupertino, CA (US)

(72) Inventors: Clarisse Mazuir, San Jose, CA (US); Brian P Graves, San Francisco, CA (US); Yong Seok Choi, Pleasanton, CA (US); Xiaofeng Tang, Santa Clara, CA (US); Syed Tauseen Aqeel Shah, San Jose, CA (US); Tao Zhan, Saratoga, CA (US); Rong Liu, Sunnyvale, CA (US); Yu P Sun, Yorba Linda, CA (US)

(21) Appl. No.: 18/193,203

(22) Filed: Mar. 30, 2023

Related U.S. Application Data
(60) Provisional application No. 63/349,957, filed on Jun. 7, 2022.

(51) Int. Cl. G09G 3/32; H01L 27/15; G02B 5/02; G02B 5/28; G02B 27/00; H01L 33/44

(52) U.S. Cl. CPC G09G 3/32; H01L 27/156; G02B 5/021; G02B 5/283; G02B 27/0068; H01L 33/44; G02B 2207/123; G09G 2300/0439

(57) ABSTRACT

A display may have a display panel with an array of pixels formed from light-emitting diodes. Optical films that help collimate and homogenize light from the light-emitting diode pixels may overlap the light-emitting diodes. A transparent cover may overlap the display. The transparent cover may have an outer surface and an opposing inner surface, which may have areas of compound surface curvature. Louvers that serve to reduce off-axis solar light reflections while allowing light from the display panel to be emitted may be formed from molded polymer supported by a transparent cover layer in the cover. A diffuser may be formed by embedding light-scattering particles in a polymer layer covering the louvers and/or by forming light-scattering surface structures such as ridges and/or other texture on the surface of the polymer layer. Electrically adjustable light modulator layers and electrically adjustable louvers may be used in the display.

This application claims the benefit of provisional patent application No. 63/349,957, filed Jun. 7, 2022, which is hereby incorporated by reference herein in its entirety.

### FIELD

This relates generally to displays, and, more particularly, to suppressing ambient light reflections for displays.

### BACKGROUND

Displays are sometimes used in bright ambient lighting conditions. Such displays may be exposed to sunlight and other bright light sources that can create undesired reflections.

### SUMMARY

A display may have a display panel with an array of pixels formed from light-emitting diodes. Optical films that help collimate and homogenize light from the light-emitting diode pixels may overlap the light-emitting diodes.

A transparent cover may overlap the display. The cover may have surfaces of compound curvature. Louvers that serve to reduce off-axis solar light reflections while allowing light from the display panel to be emitted may be formed from molded polymer supported by a transparent polymer layer in the cover. A dichroic filter formed from thin-film coating on the transparent polymer layer may be used to block ultraviolet and/or infrared light and thereby prevent damage to the louvers.

A diffuser may be formed by embedding light-scattering particles in a polymer layer covering the louvers and/or by forming light-scattering structures such as ridges and/or other texture on the surface of the polymer layer. The diffuser may have more light-diffusing structures in peripheral portions.

Electrically adjustable light modulator layers and electrically adjustable louvers may be used in the display. These adjustable components may be used to enhance display output in diming lighting conditions while increasing display contrast in bright lighting conditions.

### BRIEF DESCRIPTION OF THE DRAWINGS

FIG. 1 is a side view of an illustrative display showing how the display may include a display panel and a cover that has louvers that form a solar rejection filter in accordance with an embodiment.

FIGS. 2 and 3 are side views of illustrative covers with louvers in accordance with embodiments.

FIG. 4 is a side view of an illustrative cover with louvers in accordance with an embodiment.

FIG. 5 is a side view of an illustrative cover with louvers and optional coatings in accordance with an embodiment.

FIG. 6 is a side view of an illustrative display with an adjustable light modulator layer to selectively increase display contrast in bright ambient lighting conditions in accordance with an embodiment.

FIG. 7 is a side view of an illustrative display cover with electrically adjustable lovers in accordance with an embodiment.

### DETAILED DESCRIPTION

Displays may have pixels for displaying images. The pixels may include structures that can reflect ambient light. When used in bright ambient lighting conditions such as conditions where direct sunlight is present, there is a risk that unwanted light reflections will reduce display contrast. To avoid such contrast reductions, a display may be provided with a set of louvers. The louvers, which may be formed from horizontally oriented strips of opaque material, may serve as a solar rejection filter that helps reduce off-axis ambient light reflections such as sunlight reflections from the display. The louvers may allow display light to pass, so that text, graphics, images, and/or other content can be displayed on the display.

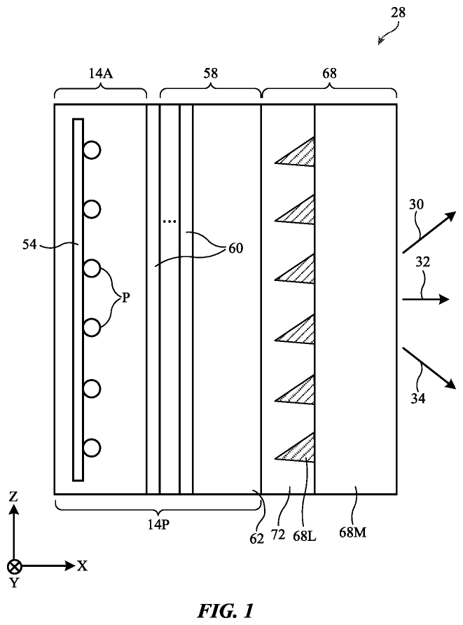

An illustrative display is shown in FIG. 1. Display 28 of FIG. 1 may have a display panel 14P (sometimes referred to as a light plate assembly, pixel array, or display). Panel 14P may include pixel array 14A, which is formed from an array of pixels P. Each pixel P may contain a respective light source such as a light-emitting diode on a printed circuit or other substrate 54. There may be any suitable number of pixels P in panel 14P (e.g., at least 100, at least 1000, at least 10,000, at least 1 million, etc.). Pixels P may have any suitable size. In an illustrative configuration, the lateral dimensions (e.g., dimensions along directions Y and Z of FIG. 1) of pixels P may be on the order of fractions of a millimeter to multiple millimeters. The light-emitting diodes of panel 14P may be configured to emit white light and/or may be configured to emit non-white light (e.g., light of one or more colors, such as red, green, blue, yellow, orange, etc.). The use of white light, which may sometimes be described herein as an example, may help make content displayed by display 28 visible and may help avoid confusion with colored light from other light sources. Display panel 14P may include light conditioning optics 58 that overlap pixels P to help collimate and homogenize light emitted by pixels P.

Panel 14P may be overlapped by protective cover 68. Cover 68 may include cover layer 68M and louvers 68L. Layer 68M may be formed from a transparent material such as clear glass or clear polymer. Louvers 68L may be formed from elongated opaque strips that extend horizontally across layer 68M (e.g., strips that extend into the page of FIG. 1).

Louvers 68L may have triangular cross-sectional shapes and/or other suitable shapes and may have sides that are angled to help block undesired light reflections will allowing display light to pass without significant attenuation. The upper and lower surfaces of louvers 68L of FIG. 1 may, as an example, have angular orientations that are configured to help block ambient sunlight reflections 34 of sunlight 30 when the sun is elevated in the sky while allowing display light 32 to be emitted horizontally over a desired angular range.

Transparent polymer 72 may cover louvers 68L. Polymer 72 may serve as a planarization layer and may be used to help protect louvers 68L and to help allow panel 14P to be mounted to cover 68 without air gaps (e.g., by using a layer of adhesive, heat and/or pressure, and/or other attachment mechanisms). The elimination of excessive air gaps may help enhance the outward appearance of display 28 (e.g., by ensuring that pixel array 14A does not visually appear to be located too far behind cover 68).

Light conditioning optics 58 of panel 14P may include, for example, reflectors, lenses (e.g., microlenses), and/or other optical elements (e.g., optics in one or more optical films 60) that help reduce divergence in the emitted light from the light-emitting diodes of pixels P. If desired, optics 58 may include an optional diffuser such as diffuser 62. Diffuser 62 may be, for example, an asymmetric diffuser that reflects sunlight asymmetrically (e.g., so that this reflected light exhibits enhanced absorption within louver layer 64). This may help to suppress solar reflections due to sunlight that could obscure the viewing of display light from panel 14P that is emitted in direction 32 for viewing by a viewer.

If desired, cover 68 may include light-diffusing structures that serve as a diffuser. For example, polymer 72 may include light-scattering particles (e.g., particles of titanium oxide, silicon oxide, and/or other inorganic dielectric particles with an index of refraction that differs from that of polymer 72) and/or other light-diffusing structures may be formed in cover 68 (e.g., surface texture such as a roughened texture, embossed ridges, and/or other surface structures that scatter light, an array of dots of white paint or other light-scattering material, etc.). When the functions of diffuser 62 are incorporated into cover 68 in this way, diffuser 62 may be omitted from panel 14P.

When display 28 is mounted on the exterior of a building or vehicle it may be desirable for display 28 to have a three-dimensional (non-planar) shape. For example, the exterior and, if desired, interior surfaces of cover 68 and/or the surfaces of one or more of the layers in display panel 14P may have areas of compound curvature (e.g., non-developable surfaces characterized by curved cross-sectional profiles when viewed in cross-section in the Y-X and X-Z planes of FIG. 1). Arrangements in which cover 68 and/or panel 14P have planar surface areas and/or developable surface areas (e.g., surfaces with zero Gaussian curvature that can be flattened without distortion) may also be used.

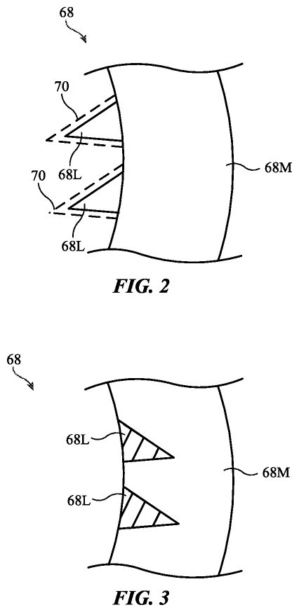

FIGS. 2 and 3 are side views of illustrative covers 68 with louvers to reduce ambient light reflections from panel 14P. As shown in FIGS. 2 and 3, cover 68 may have a curved outer (exterior) surface (e.g., the surface facing away from panel 14P may be convex and may have compound curvature). In the examples of FIGS. 2 and 3, the corresponding inner surface (sometimes referred to as the interior surface or inwardly facing surface) is also curved and may also have compound curvature. Louvers 68L may be formed by molding (e.g., injection molding, embossing, etc.). As an example, louvers 68L may be formed by molding polymer strips onto the inner surface of layer 68M of cover 68 (which may be formed from glass or polymer). If desired, layer 68M may be formed from a first shot of polymer (e.g., clear polymer) and louvers 68L may be formed from a second shot of polymer (e.g., opaque polymer), thereby creating a unitary cover with both a clear layer and overlapping strips of opaque louver structures. In some configurations, a single molding operation may be used in forming layer 68M and louvers 68L (e.g., layer 68M and louvers 68L may be formed from a single molded polymer member).

Louvers 68L may be formed from a bulk material that is opaque (e.g., polymer with embedded light-absorbing particles such as particles of carbon black or other opaque colorant such as dark dyes and/or pigments) and/or louvers 68L may be opaque by virtue of being coated with a coating 70 that is opaque. Opaque coating 70 may be formed from opaque polymer (e.g., black photosensitive polymer) or other opaque materials. Coating 70 may be patterned so that areas between adjacent louvers 68L are uncovered by opaque coating material. Coating 70 may, for example, be patterned using photolithography, laser etching, and/or other patterning techniques. Louvers 68L may, if desired, be covered with a planarizing coating such as polymer coating 72 (e.g., clear polymer). By forming louvers 68L from polymer structures that are part of layer 68M or that are molded, printed, or otherwise formed on the inner surface of layer 68M, wrinkling effects that might be present when laminating a louver film to a layer such as layer 68M with surfaces of compound curvature can be avoided.

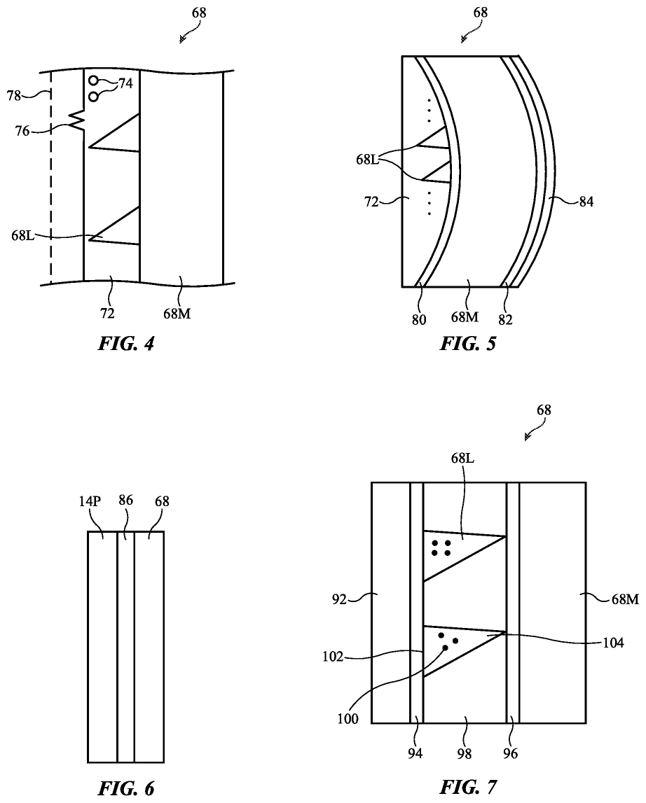

Light-diffusing structures may be incorporated into cover 68 so that the functions of diffuser 62 of FIG. 1 may be implemented within cover 68. These light-diffusing structures of cover 68 may sometimes be referred to as forming an integral diffuser within cover 68 (e.g., the diffuser portion of the cover and transparent structural portions of the cover that supply support for the cover may be formed in a unitary fashion). As shown in FIG. 4, a diffuser may be formed from light-scattering particles 74 that are embedded within polymer coating 72, may be formed from light-scattering structures 76 on the inner surface of polymer 72 (e.g., the surface may be provided with light-scattering texture such as a embossed ridges, rough texture, and/or other surface light-scattering structures), and/or may be formed using a light-scattering coating (e.g., white dots or a solid white diffusing coating) or light-scattering film such as layer 78 that is formed on polymer coating 72.

The density of light-scattering structures may vary as a function of position across layer 68M (e.g., as a function of position along the Y and Z directions of FIG. 1). Due to the bowed out cross-sectional shape of layer 68M, light from pixels P near the center of array 14A has more distance to spread laterally outward (e.g., perpendicular to the direction of travel of the light) before striking the light-scattering structures than light from pixels P that are located near the periphery of array 14A. So that the light from pixels P that passes through the diffuser has an even appearance (e.g., so that pixels P appear similar in size to an external viewer regardless of their lateral position in display 28), it may be desirable to decrease the density of the light-scattering structures towards the center of the light-scattering structures (e.g., in the center of display 28 as viewed in the −X direction of FIG. 1) relative to peripheral portions of the light-scattering structures. The higher density of light-scattering structures present near the periphery of display 28 may help compensate for the reduced distance that light from edge pixels P has to spread out before reaching the diffuser.

As shown in FIG. 5, polymer layer 72 may have a planar inwardly facing surface, which may facilitate mounting of display panel 14P to cover 68. FIG. 5 also shows how optional coatings such as coatings 80, 82, and/or 84 may be incorporated into cover 68 (e.g., cover 68 of FIG. 5 and/or other covers 68 for display 28). Coatings 80 and 82 may be thin-film interference filters (sometimes referred to as dichroic filters) that are configured to pass visible light while blocking infrared and/or ultraviolet light to help prevent solar damage to structures such as louvers 68L. Outer layer 84 may be an anti-scratch layer and may be formed from a hard clear dielectric coating such as silicon nitride, tantalum oxide (e.g., Ta₂O₅), etc.

FIG. 6 shows how an electrically adjustable light modulator (sometimes referred to as an active tint layer or light modulator layer) such as light modulator 86 may be interposed between cover 68 (and its louvers and other structures) and display panel 14P. Light modulator 86 may be an electrically adjustable guest-host liquid crystal light modulator, an electrochromic light modulator, and/or other light modulator that can be electrically adjusted to produce a desired amount of light transmission. At night or in other dim lighting conditions, light modulator 86 may be adjusted to have a relatively high transmission (e.g., more than 60%, more than 85%, or more than 95%). In bright sunlight or during other bright ambient lighting conditions, the transmission of modulator 86 may be reduced (e.g., to less than 60%, less than 50%, less than 30%, etc.) to reduce the intensity of ambient light reflections (which pass twice through modulator 86) relative to the intensity of emitted display light from array 14A (which passes once through modulator 86). In this way, the contrast of display 28 may be enhanced in bright ambient lighting.

FIG. 7 is a side view of an illustrative cover with electrically adjustable louvers. As shown in FIG. 7, cover 68 includes cover layer 68M (e.g., a glass or polymer member that may have outer and/or inner surfaces of compound curvature). Cover 68 of FIG. 7 may include electrically adjustable electronic ink louvers formed from louvers 68L that are filled with electronic ink particles 100 in solution (sometimes referred to as electrophoretic ink particles). Louvers 68L (which are elongated strips that extend into the page of FIG. 7) may be formed from louver cavities in molded polymer layer 98. Polymer layer 98 may be formed by molding a layer of clear polymer onto layer 68M. The louver cavities may be filled with particles 100 in solution by introducing the solution to the ends of the louver cavities under vacuum after sealing the cavities with polymer layer 92.

Particles 100 may be, for example, charged particles containing black pigment. Electrodes 94 and 96 may be formed from layers of conductive transparent material such as indium tin oxide. Electrode 96 may be deposited on the inner surface of layer 68M. Electrode 94 may be formed from a conductive transparent coating on a transparent substrate such as polymer layer 92 (e.g., a polymer film, a molded polymer member, etc.). During operation, an adjustable voltage may be applied across electrodes 94 and 96. In dim lighting conditions in which louvers 68L are not needed to block sunlight reflections, the voltage that is applied across terminals 94 and 96 may create an electric field through louvers 68L that moves particles 100 into tip portion 104 of louvers 68L. This reduces the volume within louvers 68L that is occupied by opaque material, thereby increasing the transparency of louvers 68L to enhance the intensity of display light that is transmitted from panel 14P through louvers 68L and cover 68 (and thereby effectively turning louvers 68L off). In bright lighting conditions in which the presence of opaque louvers 68L is desired to block sunlight reflections from display panel 14P, the voltage that is applied across terminals 94 and 96 may be adjusted so that particles 100 are evenly distributed throughout louvers 68L (e.g., so that particles 100 move away from portion 104 towards portion 102 of louvers 68L). In this way, the light-blocking capabilities of louvers 68L may be activated. In arrangements such as these in which the louvers of cover 68 can be turned on and off, it is possible to enhance the amount of display light that is output from display 28 in dim ambient lighting conditions (by turning louvers 68L off) while enhancing display contrast when bright ambient lighting conditions are present (by turning louvers 68L on).

The foregoing is merely illustrative and various modifications can be made to the described embodiments. The foregoing embodiments may be implemented individually or in any combination.

What is claimed is:

1. A display, comprising:
an array of pixels;
a transparent cover layer though which the display is visible, the transparent cover layer having a surface of compound curvature; and
molded polymer louvers supported by the transparent cover layer.

2. The display defined in claim 1 wherein the molded polymer louvers comprise opaque polymer louvers that are molded onto a side of the transparent cover layer facing the array of pixels.

3. The display defined in claim 1 wherein the molded polymer louvers have opaque coatings.

4. The display defined in claim 1 further comprising a transparent polymer planarization layer that overlaps the molded polymer louvers.

5. The display defined in claim 1 further comprising a dichroic filter configured to pass visible light while blocking ultraviolet light, wherein the molded polymer louvers are between the dichroic filer and the array of pixels.

6. The display defined in claim 5 wherein the transparent cover layer has an exterior surface and an opposing interior surface that faces the array of pixels and wherein the dichroic filter is on the exterior surface.

7. The display defined in claim 5 wherein the transparent cover layer has an exterior surface and an opposing interior surface that faces the array of pixels, wherein the dichroic filter is on the interior surface and is between the molded polymer louvers and the transparent cover layer.

8. The display defined in claim 1 wherein the transparent cover layer includes a light diffuser.

9. The display defined in claim 8 wherein the light diffuser comprises light-scattering particles in a transparent polymer planarization layer that overlaps the molded polymer louvers.

10. The display defined in claim 8 wherein the light diffuser comprises light-scattering surface structures on a surface of a transparent polymer planarization layer that overlaps the molded polymer louvers.

11. The display defined in claim 8 wherein the light diffuser comprises light-scattering structures that vary in density laterally across the light diffuser.

12. The display defined in claim 11 wherein there is a larger density of the light-scattering structures on a peripheral portion of the transparent cover layer than on a central portion of the transparent cover layer that is surrounded by the peripheral portion.

13. The display defined in claim 1 further comprising an electrically adjustable light modulator layer between the transparent cover layer and the array of pixels.

14. The display defined in claim 13 wherein the electrically adjustable light modulator comprise an electrically adjustable light modulator selected from the group consisting of: a guest-host liquid crystal light modulator and an electrochromic light modulator.

15. A display, comprising:
an array of pixels configured to emit light;
a transparent cover; and
electrically adjustable louvers between the transparent cover and the array of pixels.

16. The display defined in claim 15 wherein the electrically adjustable louvers comprise charged opaque particles in solution.

17. The display defined in claim 15 further comprising first and second transparent electrodes configured to apply an adjustable electric field to the charged opaque particles, wherein the transparent cover has first and second opposing surfaces of compound curvature.

18. A display, comprising:
pixels configured to emit light;
a transparent cover having a first side with compound surface curvature and having an opposing second side facing the pixels; and
molded polymer louvers on the second side.

19. The display defined in claim 18 further comprising:
a layer of transparent polymer that covers the molded polymer louvers; and
light-scattering particles in the layer of transparent polymer that are configured to diffuse the emitted light.

20. The display defined in claim 18 further comprising:
a layer of transparent polymer that covers the molded polymer louvers; and
light-scattering surface structures formed on a surface of the layer of transparent polymer.

21. The display defined in claim 18 wherein the transparent cover comprises a first shot of molded polymer material and the molded polymer louvers comprise a second shot of molded polymer material on the first shot.
